(19) United States
(12) Patent Application Publication
(10) Pub. No.: US 2024/0324689 A1
(43) Pub. Date: Oct. 3, 2024

(54) ELECTRONIC CIGARETTE

(71) Applicant: AAC ACOUSTIC TECHNOLOGIES (SHENZHEN) CO., LTD., Shenzhen (CN)

(72) Inventors: Jinyang Li, Shenzhen (CN); Tao Fang, Shenzhen (CN); Rui Zhang, Shenzhen (CN)

(21) Appl. No.: 18/399,756

(22) Filed: Dec. 29, 2023

Related U.S. Application Data
(63) Continuation of application No. PCT/CN2023/085982, filed on Apr. 3, 2023.

(51) Int. Cl. A24F 40/51; A24F 40/40; G01F 1/20; H05K 1/02; H05K 1/18

(52) U.S. Cl. CPC A24F 40/51; A24F 40/40; G01F 1/20; H05K 1/0206; H05K 1/181; H05K 2201/10151; H05K 2201/10522

(57) ABSTRACT

An electronic cigarette, including cigarette housing and micro-electromechanical system (MEMS) airflow sensor received in the cigarette housing. The MEMS airflow sensor includes a printed circuit board (PCB), an upper cover that covers PCB and encloses a receiving space together with PCB, and application specific integrated circuit (ASIC) chip and an MEMS chip with back cavity that are fixed to PCB and electrically connected to each other. The upper cover is provided with first sound hole passing therethrough. A side of PCB close to the upper cover and a side of PCB away from the upper cover are respectively provided with an upper metal layer and a lower metal layer that are exposed to a surface of PCB and are electrically connected to each other. A projection of ASIC chip on PCB at least partially falls within a range of the upper metal layer.

### TECHNICAL FIELD

The disclosure relates to the technical field of gas-to-electricity conversion, and in particular, to an electronic cigarette provided with an airflow sensor.

### BACKGROUND

With the rapid development of a gas-to-electricity conversion technology, an airflow sensor has gradually been applied to various industries, such as a communication device, a household voice-controlled appliance, and an entertainment device.

The airflow sensor is a transducer that converts a vibration frequency of airflow into an electronic signal. Due to advantages such as a small size, a light weight, a low cost, low power consumption, high reliability, and easy integration, an airflow sensor based on a micro-electromechanical system (MEMS) chip has been widely used.

The application of a MEMS airflow sensor to an electronic cigarette is a conventional application manner. Specifically, the MEMS airflow sensor is mounted on a cigarette housing to convert a vibration signal of airflow caused by a user during inhalation into an electronic signal, thereby taking a corresponding action based on the electronic signal.

The MEMS airflow sensor in the electronic cigarette mainly includes a printed circuit board (PCB), an upper cover that covers the PCB and encloses an accommodating space together with the PCB, and an application specific integrated circuit (ASIC) chip and an MEMS chip that are fixed to the PCB and electrically connected to each other. The ASIC chip generates heat when operating. If the heat cannot be transferred outside the accommodating space, normal operation of the ASIC chip may be affected due to overheating.

In the related art, dimensions of the MEMS airflow sensor in the electronic cigarette may generally be designed to be less than or equal to 4 mm*3 mm*1.3 mm, so the PCB thereof may also be thin. As a result, the PCB has relatively poor heat dissipation performance and cannot transfer the heat generated during operation of the ASIC chip to the outside of the accommodating space in time, thereby causing the ASIC chip to trigger overheating protection and stop operating.

Therefore, there is a need to provide an electronic cigarette with a new MEMS airflow sensor to solve the above problem.

### SUMMARY

The technical problem to be solved in the disclosure is how to provide an electronic cigarette with a new MEMS airflow sensor to solve the problem in the related art that the PCB of the MEMS airflow sensor in the electronic cigarette has relatively poor heat dissipation performance and cannot transfer the heat generated during operation of the ASIC chip to the outside, causing the ASIC chip to trigger overheating protection and stop operating.

In order to solve the above technical problem, in a first aspect, the disclosure provides an electronic cigarette, including a cigarette housing and a MEMS airflow sensor received in the cigarette housing, the MEMS airflow sensor includes a PCB, an upper cover that covers the PCB and encloses a receiving space together with the PCB, and an ASIC chip and an MEMS chip with a back cavity, the ASIC chip and the MEMS chip are fixed to the PCB, electrically connected to each other, and stored in the receiving space, and the ASIC chip is electrically connected to the PCB; the upper cover is provided with a first sound hole passing therethrough and connecting the receiving space with the outside; a side of the PCB close to the upper cover and a side of the PCB away from the upper cover are respectively provided with an upper metal layer and a lower metal layer that are exposed to a surface of the PCB and are electrically connected to each other; and a projection of the ASIC chip on the PCB at least partially falls within a range of the upper metal layer.

As an improvement, the PCB is provided with a via hole passing therethrough, the via hole is filled with a thermally conductive member; and the upper metal layer and the lower metal layer are electrically connected through the thermally conductive member.

As an improvement, an orthographic projection of the via hole to the upper metal layer at least partially falls within the range of the upper metal layer, and an orthographic projection of the via hole to the lower metal layer at least partially falls within a range of the lower metal layer.

As an improvement, the thermally conductive member is made of copper.

As an improvement, the ASIC chip is affixed to the PCB through thermally conductive adhesive with thermal conductivity greater than or equal to 0.8 W/m*K.

As an improvement, a plurality of ASIC chips are provided and are respectively electrically connected to the MEMS chip, and the plurality of ASIC chips are respectively electrically connected to the PCB.

As an improvement, the PCB is further provided with a second sound hole passing therethrough and connecting the receiving space with the outside, the second sound hole is arranged directly opposite to the back cavity; and the first sound hole is arranged on a side of the upper cover away from the PCB.

As an improvement, the ASIC chip is electrically connected to the PCB through a connecting wire; and the MEMS chip is electrically connected to the ASIC chip through the connecting wire.

As an improvement, both the upper metal layer and the lower metal layer are made of copper.

Compared with the related art, according to the MEMS airflow sensor in the electronic cigarette, the side of the PCB close to the upper cover and the side of the PCB away from the upper cover are respectively provided with the upper metal layer and the lower metal layer that are exposed to the surface of the PCB and are electrically connected to each other, and the projection of the ASIC chip on the PCB at least partially falls within the range of the upper metal layer, so that an overall thermal conduction effect of the PCB can be improved through the upper metal layer and the lower metal layer that are added, that is, heat dissipation performance of the PCB is improved, and the heat generated during operation of the ASIC chip can be transferred to the outside of the receiving space, thereby preventing stopping of the operation of the ASIC chip due to triggering of overheating protection.

### BRIEF DESCRIPTION OF DRAWINGS

In order to illustrate the technical solutions in the embodiments of the disclosure more clearly, the accompanying drawings to be used in the description of the embodiments will be briefly introduced below. Obviously, the accompanying drawings in the following description are only some embodiments of the disclosure. For those of ordinary skill in the art, other accompanying drawings can be obtained based on these drawings without creative efforts. In the drawings,

FIG. 1 is a schematic structural diagram of an electronic cigarette according to an embodiment of the disclosure; and

FIG. 2 is a sectional view of a MEMS airflow sensor in the electronic cigarette according to an embodiment of the disclosure.

In the figures, 100: MEMS airflow sensor; 1: PCB; 11: thermally conductive member; 12: second sound hole; 2: upper cover; 21: first sound hole; 3: ASIC chip; 4: MEMS chip; 41: back cavity; 5: upper metal layer; 6: lower metal layer; 7: connecting wire; 10: receiving space; 200: electronic cigarette; 201: cigarette housing.

### DESCRIPTION OF EMBODIMENTS

The technical solutions in the embodiments of the disclosure will be clearly and completely described below with reference to the accompanying drawings in the embodiments of the disclosure. Obviously, the described embodiments are only some of the embodiments of the disclosure, but not all of the embodiments. Based on the embodiments of the disclosure, all other embodiments obtained by those of ordinary skill in the art without creative efforts fall within the protection scope of the disclosure.

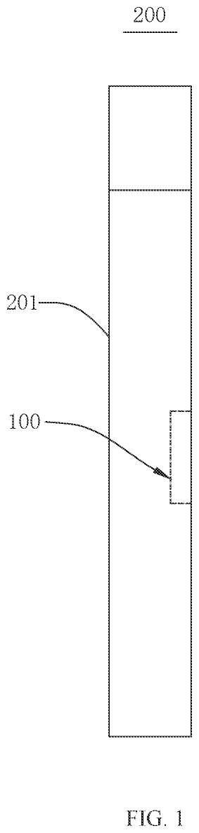

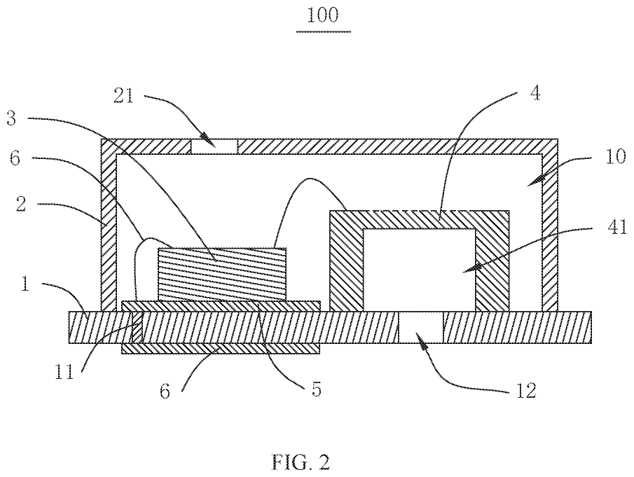

An embodiment of the disclosure provides an electronic cigarette 200, which, referring to FIG. 1 to FIG. 2, includes a cigarette housing 201 and a MEMS airflow sensor 100 received in the cigarette housing 201. The MEMS airflow sensor 100 includes a PCB 1, an upper cover 2 that covers the PCB 1 and encloses a receiving space 10 together with the PCB 1, and an ASIC chip 3 and an MEMS chip 4 with a back cavity 41 that are fixed to the PCB 1 and electrically connected to each other. The ASIC chip 3 and the MEMS chip 4 are stored in the receiving space 10, and the ASIC chip 3 is electrically connected to the PCB 1. The upper cover 2 is provided with a first sound hole 21 passing therethrough and connecting the receiving space 10 with the outside. A side of the PCB 1 close to the upper cover 2 and a side of the PCB 1 away from the upper cover 2 are respectively provided with an upper metal layer 5 and a lower metal layer 6 that are exposed to a surface of the PCB 1 and are electrically connected to each other. A projection of the ASIC chip 3 on the PCB 1 at least partially falls within a range of the upper metal layer 5.

Both the upper metal layer 5 and the lower metal layer 6 are structural layers made of metal, for example, structural layers made of metal sheets such as copper sheets, aluminum sheets, or aluminum alloy sheets.

The ASIC chip 3 may be directly fixed to the upper metal layer 5 and electrically connected to the upper metal layer 5 to indirectly achieve fixation to the PCB 1. Certainly, according to an actual requirement, the upper metal layer 5 may alternatively be buried on the side of the PCB 1 close to the upper cover 2 and the upper metal layer 5 is exposed, thereby directly fixing the ASIC chip 3 to the PCB 1. The electrical connection between the ASIC chip 3 and the upper metal layer 5 means that the two are physically connected to achieve a thermal conduction effect, not to achieve an electrical signal connection, because an electrical signal of the ASIC chip 3 is introduced or extracted from the PCB 1.

The MEMS chip 4 is a capacitive MEMS chip 4. One or more ASIC chips 3 may be provided. When a plurality of ASIC chips 3 are provided, the plurality of ASIC chips 3 are spaced apart and are respectively connected to the MEMS chip 4, and at the same time, the plurality of ASIC chips 3 are respectively electrically connected to the PCB 1. In this embodiment, one ASIC chip 3 is provided.

According to an actual requirement, the projection of the ASIC chip 3 on the PCB 1 may either partially fall within the range of the upper metal layer 5 or wholly fall within the range of the upper metal layer 5. When the projection wholly falls within the range of the upper metal layer 5, the heat generated during operation of the ASIC chip 3 may be transferred to the outside of the receiving space 10 more quickly through the upper metal layer 5.

In addition, the projection of the ASIC chip 3 on the PCB 1 may alternatively partially or wholly fall within a range of the lower metal layer 6. Correspondingly, the upper metal layer 5 and the lower metal layer 6 may be arranged completely opposite to each other, or may be arranged partially opposite to each other.

In this embodiment, the PCB 1 is further provided with a second sound hole 12 passing therethrough and connecting the receiving space 10 with the outside, and the second sound hole 12 is arranged directly opposite to the back cavity 41. The first sound hole 21 is arranged on a side of the upper cover 2 away from the PCB 1.

The second sound hole 12 and the first sound hole 21 have a same function, and are both used to transmit an airflow signal to a diaphragm of the MEMS chip 4, thereby realizing conversion between the airflow signal and the electronic signal. Certainly, according to an actual requirement, only the first sound hole 21 may be provided, which also enables the airflow signal to be transferred to the diaphragm of the MEMS chip 4.

In this embodiment, the upper cover 2 is made of a metal material, and the upper cover 2 and the PCB 1 together enclose a circular receiving space 10. Certainly, according to an actual requirement, the receiving space 10 enclosed by the upper cover 2 and the PCB 1 together may alternatively be designed into other shapes, such as a rectangle, an ellipse, or a trapezoid.

In this embodiment, the ASIC chip 3 is electrically connected to the PCB 1 through a connecting wire 7, and the MEMS chip 4 is electrically connected to the ASIC chip 3 through the connecting wire 7. Specifically, the ASIC chip 3 is electrically connected to the PCB 1 through the connecting wire 7. The ASIC chip 3 may be electrically connected to the upper metal layer 5 through the corresponding connecting wire 7 and then indirectly electrically connected to the PCB 1 through the upper metal layer 5, or the ASIC chip 3 passes through the upper metal layer 5 through the corresponding connecting wire 7 and is electrically connected to the PCB 1.

In this embodiment, the PCB 1 is provided with a via hole (not shown) passing therethrough, the via hole is filled with a thermally conductive member 11, and the upper metal layer 5 and the lower metal layer 6 are electrically connected through the thermally conductive member 11. In this way, the electrical connection between the upper metal layer 5 and the lower metal layer 6 can be realized, and an overall heat dissipation effect of the PCB 1 can also be improved through the thermally conductive member 11, so as to more quickly transfer the heat generated during operation of the ASIC chip 3 to the outside of the receiving space 10.

In addition, an orthographic projection of the via hole to the upper metal layer 5 at least partially falls within the range of the upper metal layer 5, and an orthographic projection of the via hole to the lower metal layer 6 at least partially falls within the range of the lower metal layer 6. In this way, a thermal conduction effect of the thermally conductive member can be improved, so as to more quickly transfer the heat generated during operation of the ASIC chip 3 to the outside of the receiving space 10.

According to an actual requirement, one or more via holes may be provided. The thermally conductive member 11 is made of a thermally conductive and electrically conductive material, such as copper, aluminum, or an aluminum alloy.

In this embodiment, the ASIC chip 3 is affixed to the PCB 1 through thermally conductive adhesive with thermal conductivity greater than or equal to 0.8 W/m*K. In this way, the heat generated during operation of the ASIC chip 3 cannot be quickly transferred to the PCB 1 through the thermally conductive adhesive (not shown), and the heat is transferred to the outside of the receiving space 10 through the upper metal layer 5 and the lower metal layer 6.

In this embodiment, a process of conversion between the airflow signal of the MEMS airflow sensor 100 and the electronic signal is as follows. When the user inhales, the airflow signal may be transmitted from the first sound hole 21 to the receiving space 10 to cause the diaphragm of the MEMS chip 4 to vibrate, thereby causing MEMS capacitance to change. When the ASIC chip detects this change, a corresponding action may be taken, or the airflow signal is transmitted to the back cavity from the second sound hole 12 to cause the diaphragm of the MEMS chip 4 to vibrate, thereby realizing the conversion between the airflow signal and the electronic signal.

Compared with the related art, according to the MEMS airflow sensor 100 in the electronic cigarette 200, the side of the PCB 1 close to the upper cover 2 and the side of the PCB 1 away from the upper cover 2 are respectively provided with the upper metal layer 5 and the lower metal layer 6 that are exposed to the surface of the PCB 1 and are electrically connected to each other, and the projection of the ASIC chip 3 on the PCB 1 at least partially falls within the range of the upper metal layer 5, so that an overall thermal conduction effect of the PCB 1 can be improved through the upper metal layer 5 and the lower metal layer 6 that are added, that is, heat dissipation performance of the PCB 1 is improved, and the heat generated during operation of the ASIC chip 3 can be transferred to the outside of the receiving space 10, thereby preventing stopping of the operation of the ASIC chip 3 due to triggering of overheating protection.

The above are merely the embodiments of the disclosure. It should be noted herein that, for those of ordinary skill in the art, improvements can be made without departing from the creative concept of the disclosure, but these all fall within the protection scope of the disclosure.

What is claimed is:

1. An electronic cigarette, comprising a cigarette housing and a micro-electromechanical system (MEMS) airflow sensor received in the cigarette housing, wherein
the MEMS airflow sensor comprises a printed circuit board (PCB), an upper cover that covers the PCB and encloses a receiving space together with the PCB, and an application specific integrated circuit (ASIC) chip and an MEMS chip with a back cavity, the ASIC chip and the MEMS chip are fixed to the PCB, electrically connected to each other, and stored in the receiving space, and the ASIC chip is electrically connected to the PCB;
the upper cover is provided with a first sound hole passing therethrough and connecting the receiving space with outside;
a side of the PCB close to the upper cover is with an upper metal layer and a side of the PCB away from the upper cover is provided with a lower metal layer, the upper metal layer and the lower metal layer are exposed to a surface of the PCB and are electrically connected to each other; and
a projection of the ASIC chip on the PCB at least partially falls within a range of the upper metal layer.

2. The electronic cigarette as described in claim 1, wherein the PCB is provided with a via hole passing therethrough, the via hole is filled with a thermally conductive member; and the upper metal layer and the lower metal layer are electrically connected through the thermally conductive member.

3. The electronic cigarette as described in claim 2, wherein an orthographic projection of the via hole to the upper metal layer at least partially falls within the range of the upper metal layer, and
an orthographic projection of the via hole to the lower metal layer at least partially falls within a range of the lower metal layer.

4. The electronic cigarette as described in claim 2, wherein the thermally conductive member is made of copper.

5. The electronic cigarette as described in claim 1, wherein the ASIC chip is affixed to the PCB through thermally conductive adhesive having thermal conductivity greater than or equal to 0.8 W/m*K.

6. The electronic cigarette as described in claim 1, wherein a plurality of ASIC chips is provided and is respectively electrically connected to the MEMS chip, and the plurality of ASIC chips is respectively electrically connected to the PCB.

7. The electronic cigarette as described in claim 1, wherein the PCB is further provided with a second sound hole passing therethrough and connecting the receiving space with outside, the second sound hole is arranged directly opposite to the back cavity; and the first sound hole is arranged on a side of the upper cover away from the PCB.

8. The electronic cigarette as described in claim 1, wherein the ASIC chip is electrically connected to the PCB through a connecting wire; and
the MEMS chip is electrically connected to the ASIC chip through the connecting wire.

9. The electronic cigarette as described in claim 1, wherein both the upper metal layer and the lower metal layer are made of copper.
